(19) United States
(12) Patent Application Publication
(10) Pub. No.: US 2026/0372183 A1
(43) Pub. Date: Nov. 19, 2026

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Seung Ju OH, Gyeonggi-do (KR)

(21) Appl. No.: 19/333,273

(22) Filed: Sep. 18, 2025

(30) Foreign Application Priority Data
May 14, 2025 (KR) 10-2025-0062439

(51) Int. Cl. H10W 90/00; H10B 41/27; H10B 43/27; H10B 80/00; H10D 80/30

(52) U.S. Cl. CPC H10W 90/00; H10B 41/27; H10B 43/27; H10B 80/00; H10D 80/30; H10W 90/792

(57) ABSTRACT

A semiconductor device includes a gate structure including a first sub-gate structure and a second sub-gate structure, the first sub-gate structure including first insulating layers and first conductive layers that are alternately stacked, and the second sub-gate structure being disposed on the first sub-gate structure and including second insulating layers and second conductive layers that are alternately stacked; a first sub-channel structure extending through the first sub-gate structure and including a first portion and second portions protruding from the first portion toward the first sub-gate structure; and a second sub-channel structure extending through the second sub-gate structure and connected to the first sub-channel structure.

### CROSS-REFERENCE TO RELATED APPLICATION

This application claims priority under 35 U.S.C. §119 to Korean Patent Application No. 10-2025-0062439 filed on May 14, 2025, which is incorporated herein by reference in its entirety.

### BACKGROUND

### Technical Field

Embodiments of the present disclosure relate to an electronic device and a method of manufacturing the electronic device, and more particularly, to a semiconductor device and a method of manufacturing the semiconductor device.

### Related Art

The degree of integration of a semiconductor device is mainly determined by the area occupied by a unit memory cell. Recently, as improvements in the degree of integration of a semiconductor device that employs memory cells formed in a single layer on a substrate reach a limit, a three-dimensional semiconductor device that stacks memory cells in multiple layers on a substrate has been proposed. Furthermore, for improving the operational reliability of such a semiconductor device, various structures and manufacturing methods have been developed. However, further improvements are needed.

### SUMMARY

An embodiment of the present disclosure provides a three-dimensional semiconductor device (hereinafter simply referred to as a semiconductor device) that has a stable structure.

Another embodiment of the present disclosure provides a semiconductor device that exhibits improved characteristics.

Yet another embodiment of the present disclosure provides a method of manufacturing for the inventive semiconductor device.

In an embodiment of the present disclosure, a semiconductor device may include a gate structure including a first sub-gate structure and a second sub-gate structure, the first sub-gate structure including first insulating layers and first conductive layers that are alternately stacked, and the second sub-gate structure being disposed on the first sub-gate structure and including second insulating layers and second conductive layers that are alternately stacked; a first sub-channel structure extending through the first sub-gate structure and including a first portion and second portions protruding from the first portion toward the first sub-gate structure; and a second sub-channel structure extending through the second sub-gate structure and connected to the first sub-channel structure.

In another embodiment of the present disclosure, a semiconductor device may include a stack including a first sub-stack and a second sub-stack, the first sub-stack including first material layers and second material layers that are alternately stacked, and the second sub-stack being disposed on the first sub-stack and including third material layers and fourth material layers that are alternately stacked; a first through-structure extending through the first sub-stack and including a first portion and second portions protruding from the first portion toward the first sub-stack; and a second through-structure extending through the second sub-stack and connected to the first through-structure.

In yet another embodiment of the present disclosure, a method of manufacturing a semiconductor device may include forming a first sub-stack by alternately stacking first material layers and second material layers; forming a second sub-stack by alternately stacking third material layers and fourth material layers on the first sub-stack; forming a channel hole including a first sub-channel hole and a second sub-channel hole, the first sub-channel hole extending through the first sub-stack, and the second sub-channel hole extending through the second sub-stack and being connected to the first sub-channel hole; forming a sacrificial layer including a first sub-sacrificial layer and a second sub-sacrificial layer, the first sub-sacrificial layer filling the first sub-channel hole, and the second sub-sacrificial layer filling a portion of the second sub-channel hole; exposing the fourth material layers by removing the second sub-sacrificial layer; selectively forming protective patterns on the fourth material layers, respectively; exposing the second material layers by removing the first sub-sacrificial layer; and forming first openings by partially etching the second material layers, the first openings expanding the first sub-channel hole.

These and other features and advantages of the embodiments of the present disclosure will become apparent to those skilled in the art from the following detailed description in conjunction with the following drawings.

### BRIEF DESCRIPTION OF THE DRAWINGS

FIGS. 1A and 1B are simplified diagrams illustrating a semiconductor device in accordance with an embodiment of the present disclosure.

FIG. 2 is a simplified diagram illustrating a semiconductor device in accordance with an embodiment of the present disclosure.

FIG. 3 is a simplified diagram illustrating a semiconductor device in accordance with an embodiment of the present disclosure.

FIG. 4 is a simplified diagram illustrating a semiconductor device in accordance with an embodiment of the present disclosure.

FIGS. 5A, 5B, 5C, 5D, 5E, 5F, 5G, 5H, and 5I are simplified diagrams illustrating a method of manufacturing a semiconductor device in accordance with an embodiment of the present disclosure.

FIGS. 6A and 6B are simplified diagrams illustrating a method of manufacturing a semiconductor device in accordance with an embodiment of the present disclosure.

### DETAILED DESCRIPTION

Various embodiments of the present disclosure are directed to a semiconductor device having a stable structure and improved characteristics and a method of manufacturing the semiconductor device.

According to the present technology, it is possible to provide a semiconductor device having a stable structure and improved reliability.

Hereafter, embodiments in accordance with the technical concepts of the present disclosure will be described with reference to the accompanying drawings.

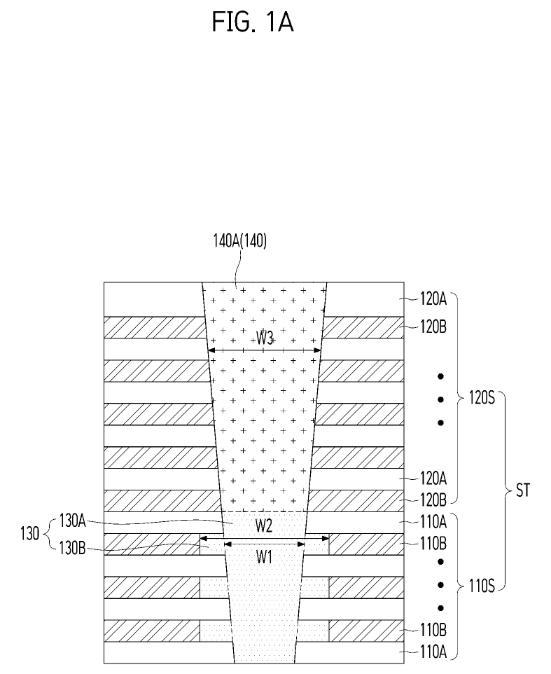

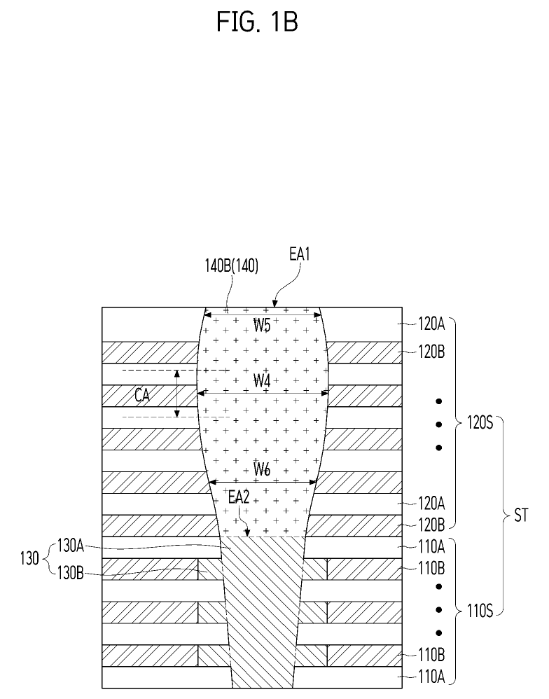

FIGS. 1A and 1B are simplified diagrams illustrating a semiconductor device in accordance with an embodiment of the present disclosure.

Referring to FIGS. 1A and 1B, the semiconductor device may include a stack ST, a first through-structure 130 formed inside the stack ST, and a second through-structure 140 formed inside the stack ST and over the first through stack ST.

The stack ST may include a first sub-stack 110S and a second sub-stack 120S disposed on the first sub-stack 110S. The first sub-stack 110S may include first material layers 110A and second material layers 110B that are alternately stacked. The second sub-stack 120S may include third material layers 120A and fourth material layers 120B that are alternately stacked. Here, the first material layers 110A and the third material layers 120A may each include an insulating material such as, for example, an oxide. The second material layers 110B and the fourth material layers 120B may each include a conductive material such as, for example, tungsten, molybdenum, or polysilicon.

The stack ST may be a gate structure. In addition, the second and fourth material layers 110B and 120B may be gate lines such as select lines, word lines, or bit lines. Source select transistors, memory cells, or drain select transistors may be disposed in regions where channel structures and the second and fourth material layers 110B and 120B intersect each other. For example, at least one source select transistor, a plurality of memory cells, and at least one drain select transistor that are stacked along the channel structure may constitute one memory string.

The first through-structure 130 may extend through the first sub-stack 110S. The first through-structure 130 may include a first portion 130A and a plurality of second portions 130B. Here, the second portions 130B may protrude from the first portion 130A toward the first sub-stack 110S. For example, the second portions 130B may protrude from the first portion 130A toward the second material layers 110B of the first sub-stack 110S. The first portion 130A may have a width that decreases from an upper surface thereof toward a lower surface thereof. For example, the first portion 130A may have a tapered shape in a cross section.

The second through-structure 140 may extend through the second sub-stack 120S, and may be connected to the first through-structure 130. The second through-structure 140 may have various shapes. For example, referring to FIG. 1A, the second through-structure 140A may have a width that decreases from an upper surface thereof toward a lower surface thereof. The second through-structure 140 may have a tapered shape in a cross section. Referring to FIG. 1B, the second through-structure 140B may have a curved surface on a sidewall thereof. For example, the second through-structure 140B may have a bow shape in a cross section. The second through-structure 140B may have a maximum width at a middle portion CA, and may have a width that decreases from the middle portion CA toward both ends EA1 and EA2.

The first through-structure 130 may have different widths at different levels thereof. For example, the first through-structure 130 may have a first width W1 at levels corresponding to the first material layers 110A, and may have a second width W2 different from the first width W1 at levels corresponding to the second material layers 110B. The second width W2 may be wider than the first width W1. For reference, the second and first widths W2 and W1 may be widths for one second material layer 110B defined as a reference and the first material layers 110A in contact with the second material layer 110B above and below the second material layer 110B defined as the reference.

Namely, the second width W2 corresponds to the width of the first-through structure 130 at the levels of the second material layers 110B and may be the same or unchanged regardless of the level of the second material layers 110B. The first width W1 is the width of the first-through structure 130 at the levels corresponding to the first material layers 110A, and may change depending on the level of the corresponding first material layer 110A.

The first through-structure 130 may have a relatively wider width at a level at which it includes both the first portion 130A and the second portion 130B than at a level at which it includes only the first portion 130A. That is, the first through-structure 130 may have a relatively great width through the second portions 130B protruding from the first portion 130A. In such a case, the first through-structure 130 may include protrusion portions, and may have a width wider than that in a case where the first through-structure 130 does not include the protrusion portions, such that support force may be increased.

The second through-structure 140 may have different widths at different levels thereof. For example, as illustrated in FIG. 1A, the second through-structure 140A may have a third width W3 that may decrease from an upper surface (e.g., a top surface) of the second through-structure 140A toward a lower surface (e.g., a bottom surface) of the second through-structure 140A. In another example illustrated in FIG. 1B, the second through-structure 140B may have a fourth width W4 at the middle portion CA, a fifth width W5 at the first end EA1, and a sixth width W6 at the second end EA2. The fourth width W4 may be a maximum width, and the second through-structure 140B may have the fifth and sixth widths W5 and W6 narrower than the fourth width W4 from the middle portion CA toward the ends EA1 and EA2. The change from the wider fourth width W4 to the narrower fifth and sixth widths W5 and W6 may be gradual so that the second through structure 140B may have a smooth curved side surface.

For reference, the first and second through-structures 130 and 140 may include various structures. For example, the first and second through-structures 130 and 130 may each include a channel structure, a slit structure, a contact via, a support, a contact plug, and the like. The channel structure may include at least one of a channel layer, a memory layer surrounding the channel layer, and an insulating core disposed in the channel layer. The slit structure may include at least one of an insulating material, a conductive material, or a semiconductor material. The contact via or the contact plug may include a conductive material such as tungsten. The support may include an insulating material such as oxide. Alternatively, the support may include a dummy channel structure having a structure similar to the channel structure.

According to the structure described above, the first through-structure 130 may include the protrusion portions at the levels corresponding to the second material layers 110B. Because the first through-structure 130 includes the protrusion portions, the support force may increase compared to the case where the first through-structure 130 does not include the protrusion portions.

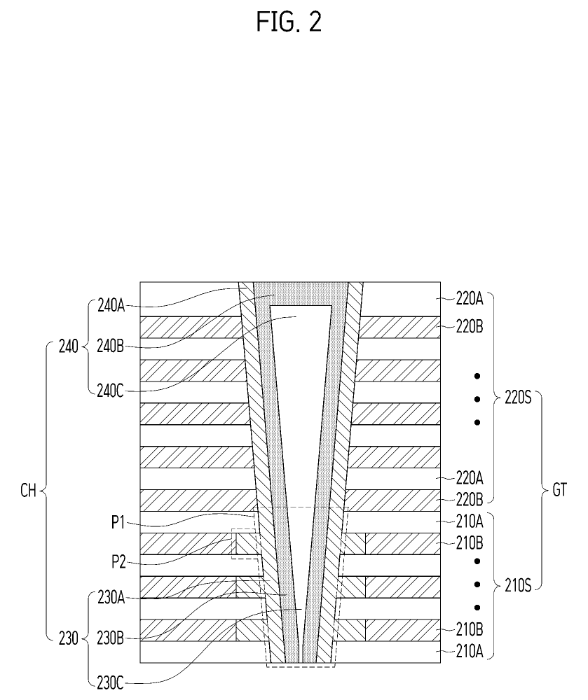

FIG. 2 is a simplified diagram illustrating a semiconductor device in accordance with an embodiment of the present disclosure. Hereinafter, content overlapping with previously described content may be omitted.

Referring to FIG. 2, the semiconductor device may include a gate structure GT, a first sub-channel structure 230, and a second sub-channel structure 240.

The gate structure GT may include a first sub-gate structure 210S and a second sub-gate structure 220S disposed on the first sub-gate structure 210S. The first sub-gate structure 210S may include first insulating layers 210A and first conductive layers 210B that are alternately stacked. The second sub-gate structure 220S may include second insulating layers 220A and second conductive layers 220B that are alternately stacked. The first and second insulating layers 210A and 220A may each include an insulating material such as oxide, and the first and second conductive layers 210B and 220B may each include a conductive material such as tungsten, molybdenum, or polysilicon.

A channel structure CH may include the first sub-channel structure 230 and the second sub-channel structure 240 disposed on the first sub-channel structure 230. The first sub-channel structure 230 may extend through the first sub-gate structure 210S, and may include a first portion P1 and second portions P2 protruding from the first portion P1. Here, the second portions P2 may protrude from the first portion P1 toward the first sub-gate structure 210S. For example, the second portions P2 may protrude from the first portion P1 toward the first conductive layers 210B of the first sub-gate structure 210S. The first portion P1 may have a width that decreases from an upper surface thereof toward a lower surface thereof. For example, the first portion P1 may have a tapered shape in a cross section.

The first sub-channel structure 230 may include at least one of a first sub-memory layer 230A, a first sub-channel layer 230B, and a first sub-insulating core 230C. For example, the first sub-channel structure 230 may include a first sub-memory layer 230A included in the first portion P1 and the second portions P2, a first sub-channel layer 230B disposed on the first sub-memory layer 230A, and a first sub-insulating core 230C disposed on the first sub-channel layer 230B. The first sub-insulating core 230C may fill the space left between the first sub-channel layer 230B which is formed on the first sub-memory layer 230A.

The second sub-channel structure 240 may extend through the second sub-gate structure 220S, and may be connected to the first sub-channel structure 230. The second sub-channel structure 240 may have a width that decreases from an upper surface thereof toward a lower surface thereof. For example, the second sub-channel structure 240 may have a tapered shape in a cross section.

For reference, although not illustrated in FIG. 2, the second sub-channel structure 240 may have a curved surface on a sidewall thereof. For example, the second sub-channel structure 240 may have a bow shape in a cross section. The second sub-channel structure 240 may have a maximum width at a middle portion, and may have a width that decreases from the middle portion toward both ends similar to the embodiment illustrated in FIG. 1B.

The second sub-channel structure 240 may include at least one of a second sub-memory layer 240A, a second sub-channel layer 240B, and a second sub-insulating core 240C. For example, the second sub-channel structure 240 may include a second sub-memory layer 240A that may extend through the second sub-gate structure 220S and is connected to the first sub-memory layer 230A, a second sub-channel layer 240B that may be disposed on the second sub-memory layer 240A and is connected to the first sub-channel layer 230B, and a second sub-insulating core 240C that may be disposed on the second sub-channel layer 240B and is connected to the first sub-insulating core 230C.

For reference, the channel structure CH may be used as a dummy channel structure. For example, the first and second sub-memory layers 230A and 240A, the first and second sub-channel layers 230B and 240B, and the first and second sub-insulating cores 230C and 240C may be used as dummy sub-memory layers, dummy sub-channel layers, and dummy sub-insulating cores, respectively. In such a case, the channel structure CH may be used as a support. The channel structure CH, when used as a dummy, may serve as a mechanical support to stabilize surrounding dummy layers and maintain structural integrity during the fabrication of the memory device.

According to the structure described above, the first sub-channel structure 230 of the channel structure CH may include the second portions P2 as protrusion portions. In such a case, the support force of the first sub-channel structure 230 may be improved.

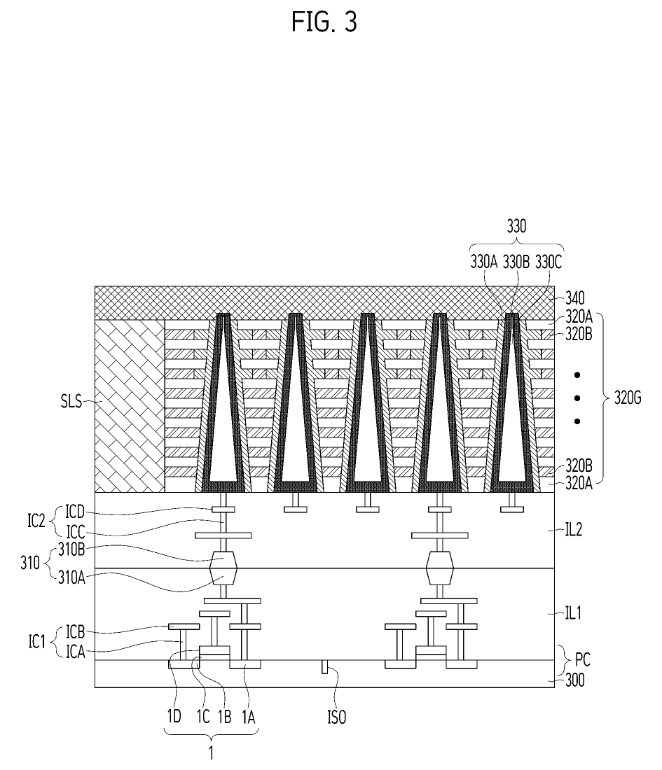

FIG. 3 is a simplified diagram illustrating a semiconductor device in accordance with an embodiment of the present disclosure. Hereinafter, content overlapping with previously described content may be omitted.

Referring to FIG. 3, the semiconductor device may include a peripheral circuit PC, a bonding structure 310, a gate structure 320G, a channel structure 330, and a source structure 340. The semiconductor device may further include a substrate 300, a first interconnection structure IC1, a second interconnection structure IC2, a first interlayer insulating layer IL1, a second interlayer insulating layer IL2, and a slit structure SLS.

The peripheral circuit PC may be disposed on the substrate 300. The peripheral circuit PC may include a transistor 1, a capacitor, resistors, inductors, diodes, logic gates, buffers, and the like. The transistor 1 may include junctions 1A and 1B, a gate electrode 1D, and a gate insulating layer 1C. Here, the gate insulating layer 1C may be disposed between the gate electrode 1D and the substrate 300. An element isolation layer ISO may be disposed in the substrate 300, an active region may be defined by the element isolation layer ISO, and the transistor 1 may be disposed in the active region.

The first interconnection structure IC1 may be disposed on the peripheral circuit PC. The first interconnection structure IC1 may be disposed in the first interlayer insulating layer IL1. Here, the first interlayer insulating layer IL1 may be disposed on the substrate 300. The first interconnection structure IC1 may include first vias ICA and first wiring lines ICB. At least one of the first vias ICA may be connected to the peripheral circuit PC. One of the first wiring lines ICB may connect the first vias ICA to each other. The first interconnection structure IC1 may include a conductive material such as tungsten. The first interlayer insulating layer IL1 may include an insulating material such as oxide.

The bonding structure 310 may be disposed on the peripheral circuit PC. For example, the bonding structure 310 may be disposed on the first interconnection structure IC1. The bonding structure 310 may include first bonding pads 310A and second bonding pads 310B. The first bonding pads 310A may be disposed in the first interlayer insulating layer IL1. The second bonding pads 310B may be disposed on the first bonding pads 310A, and may be disposed in the second interlayer insulating layer IL2. Here, the second interlayer insulating layer IL2 may be disposed on the first interlayer insulating layer IL1. The bonding structure 310 may include a conductive material such as copper. The second interlayer insulating layer IL2 may include an insulating material such as oxide or nitride.

The second interconnection structure IC2 may be disposed on the bonding structure 310. The second interconnection structure IC2 may be disposed in the second interlayer insulating layer IL2. The second interconnection structure IC2 may include second vias ICC and second wiring lines ICD. At least one of the second vias ICC may be connected to the bonding structures 310. One of the second wiring lines ICD may connect the second vias ICC to each other. The second interconnection structure IC2 may include a conductive material such as tungsten.

The gate structure 320G may be disposed on the bonding structure 310. The gate structure 320G may include insulating layers 320A and conductive layers 320B that are alternately stacked. The channel structures 330 may extend into the source structure 340 through the gate structure 320G. Here, the source structure 340 may be disposed on the gate structure 320G. Each of the channel structures 330 may include a memory layer 330A, a channel layer 330B disposed on the memory layer 330A, and an insulating core 330C disposed on the channel layer 330B. Here, the channel layer 330B may be connected to the source structure 340.

For reference, the channel structures 330 may each have a similar shape to one of the first and second through-structures 130 and 140 of FIGS. 1A and 1B and the channel structure CH of FIG. 2. For example, each of the channel structures 330 may include a first sub-channel structure and a second sub-channel structure. The first sub-channel structure may include a first portion and second portions protruding from the first portion. The first portion of the first sub-channel structure may have a tapered shape in a cross section. The second sub-channel structure may have a tapered shape in a cross section. Alternatively, the second sub-channel structure may have a curved surface on a sidewall thereof.

The slit structure SLS may extend through the gate structure 320G. The slit structure SLS may include an insulating material, a conductive material, a semiconductor material, or the like.

According to the structure described above, the semiconductor device may include the bonding structure 310. The bonding structure 310 may be disposed between the peripheral circuit PC and the gate structure 320G, and may electrically connect the channel structures 330 and the peripheral circuit PC to each other. Hence, the bonding structure 310 may electrically connect the peripheral circuit PC and the channel structures 330 while also serving as a physical interface between different regions of the semiconductor device, enabling signal transmission and integration across layers.

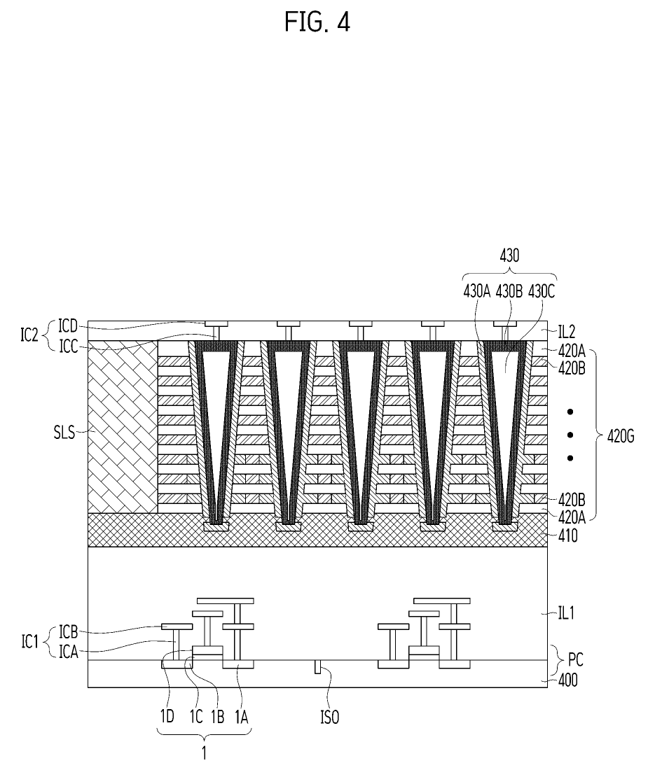

FIG. 4 is a simplified diagram illustrating a semiconductor device in accordance with an embodiment of the present disclosure. Hereinafter, content overlapping with previously described content may be omitted.

Referring to FIG. 4, the semiconductor device may include a peripheral circuit PC, a source structure 410, a gate structure 420G, and a channel structure 430. The semiconductor device may further include a substrate 400, a first interconnection structure IC1, a second interconnection structure IC2, a first interlayer insulating layer IL1, a second interlayer insulating layer IL2, and a slit structure SLS.

The peripheral circuit PC may be disposed on the substrate 400. The peripheral circuit PC may include a transistor 1, a capacitor, resistors, inductors, diodes, logic gates, buffers, and the like. The transistor 1 may include junctions 1A and 1B, a gate electrode 1D, and a gate insulating layer 1C. An element isolation layer ISO may be disposed in the substrate 400.

The first interconnection structure IC1 may be disposed on the peripheral circuit PC. The first interconnection structure IC1 may be disposed in the first interlayer insulating layer IL1. Here, the first interlayer insulating layer IL1 may be disposed on the substrate 400. The first interconnection structure IC1 may include first vias ICA and first wiring lines ICB. At least one of the first vias ICA may be connected to the peripheral circuit PC. One of the first wiring lines ICB may connect the first vias ICA to each other. The first interconnection structure IC1 may include a conductive material such as tungsten. The first interlayer insulating layer IL1 may include an insulating material such as oxide.

The gate structure 420G may be disposed on the source structure 410. Here, the source structure 410 may be disposed between the peripheral circuit PC and the gate structure 420G. The gate structure 420G may include insulating layers 420A and conductive layers 420B that are alternately stacked.

The channel structures 430 may extend into the source structure 410 through the gate structure 420G. Each of the channel structures 430 may include a memory layer 430A, a channel layer 430B, and an insulating core 430C. The channel layer 430B may be connected to the source structure 410. The channel layer 430B may also be connected to the second interconnection structure IC2 that is formed in the second interlayer insulating layer IL2.

For reference, the channel structures 430 may each have a similar shape to one of the first and second through-structures 130 and 140 of FIGS. 1A and 1B and the channel structure CH of FIG. 2. For example, each of the channel structures 430 may include a first sub-channel structure and a second sub-channel structure. The first sub-channel structure may include a first portion and second portions protruding from the first portion. The first portion of the first sub-channel structure may have a tapered shape in a cross section. The second sub-channel structure may have a tapered shape in a cross section. Alternatively, the second sub-channel structure may have a curved surface on a sidewall thereof.

The slit structure SLS may extend through the gate structure 420G. For example, the slit structure SLS may extend into the source structure 410 through the gate structure 420G. The slit structure SLS may include an insulating material, a conductive material, a semiconductor material, or the like.

The second interconnection structure IC2 may be disposed on the gate structure 420G. The second interconnection structure IC2 may be disposed in the second interlayer insulating layer IL2. Here, the second interlayer insulating layer IL2 may be disposed on the gate structure 420G. The second interconnection structure IC2 may include second vias ICC and second wiring lines ICD. At least one of the second vias ICC may be connected to the channel structures 430. One of the second wiring lines ICD may connect the second vias ICC to each other. The second interconnection structure IC2 may include a conductive material such as tungsten.

According to the structure illustrated in FIG. 4, the source structure 410 may be disposed between the peripheral circuit PC and the gate structure 420G. The channel structures 430 may be spaced apart from each other and may each extend into the source structure 410 through the gate structure 420G, and the channel layer 430B of the channel structures 430 may be connected to the source structure 410.

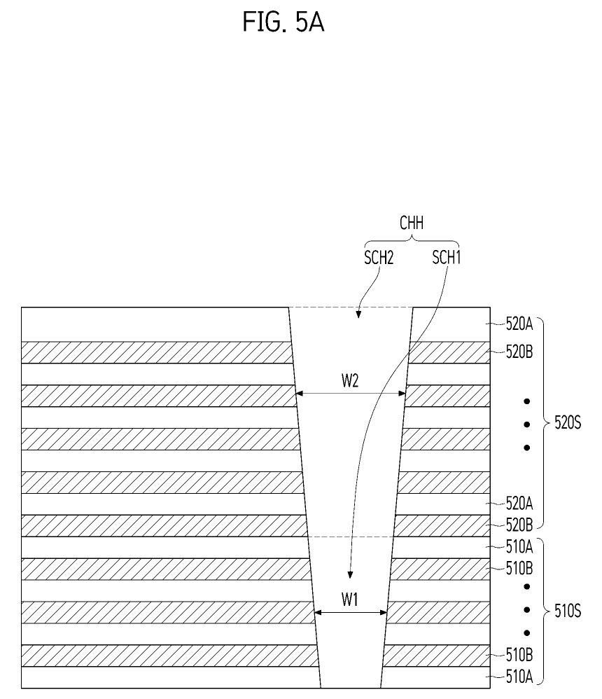

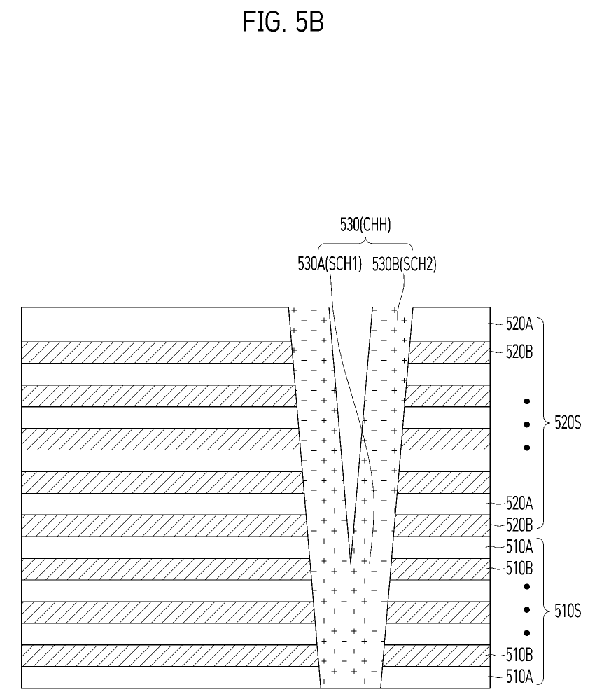

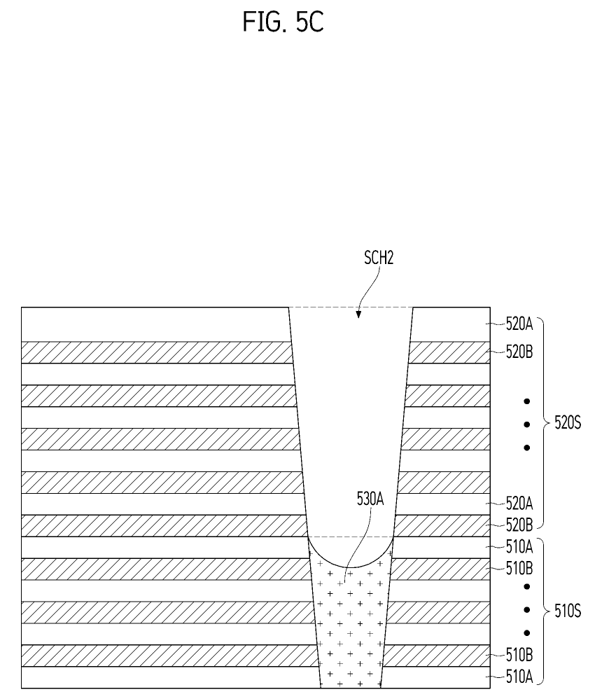

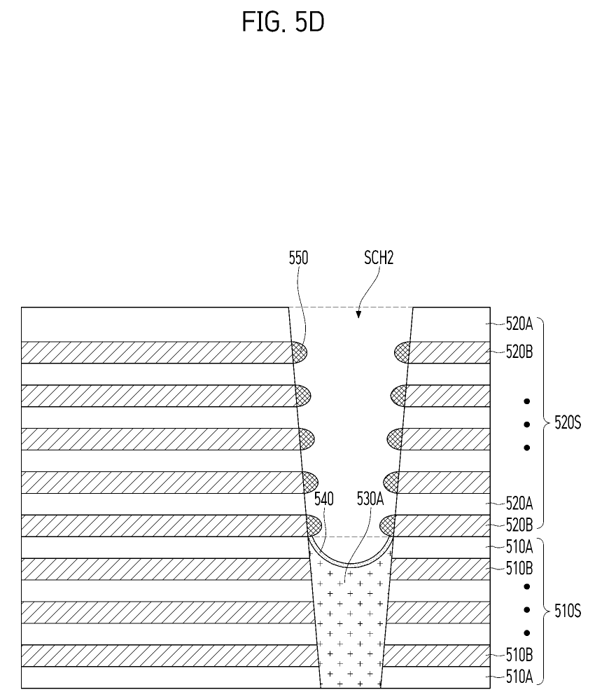

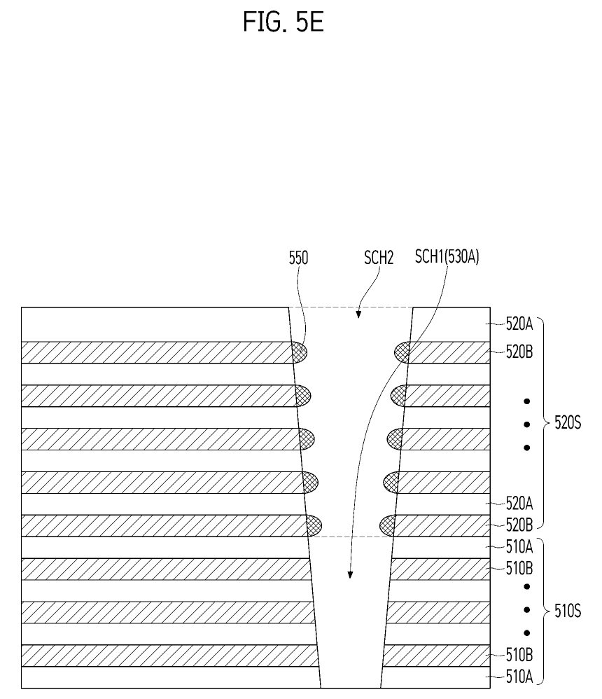

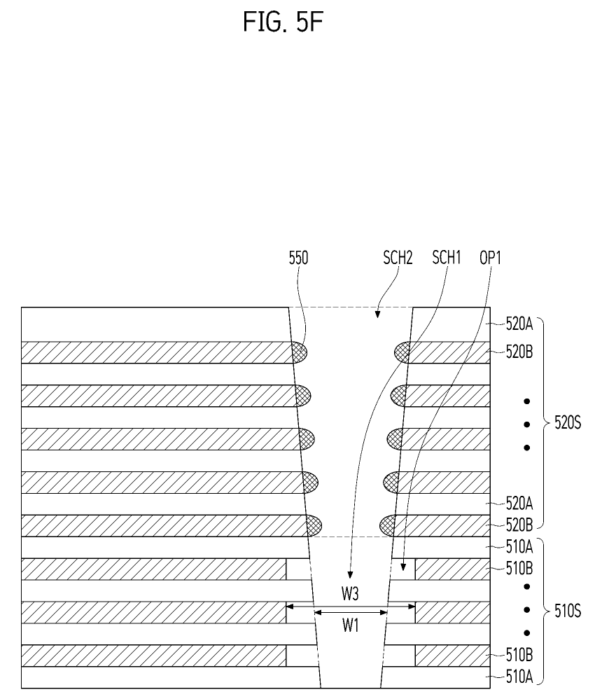

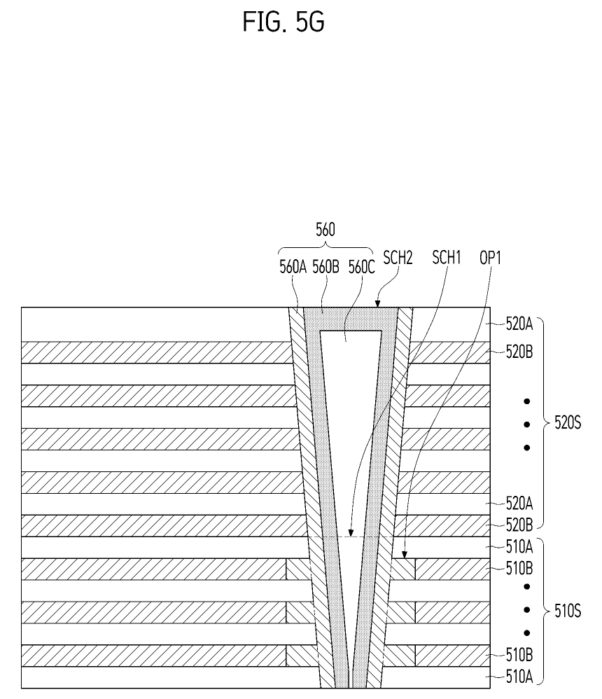

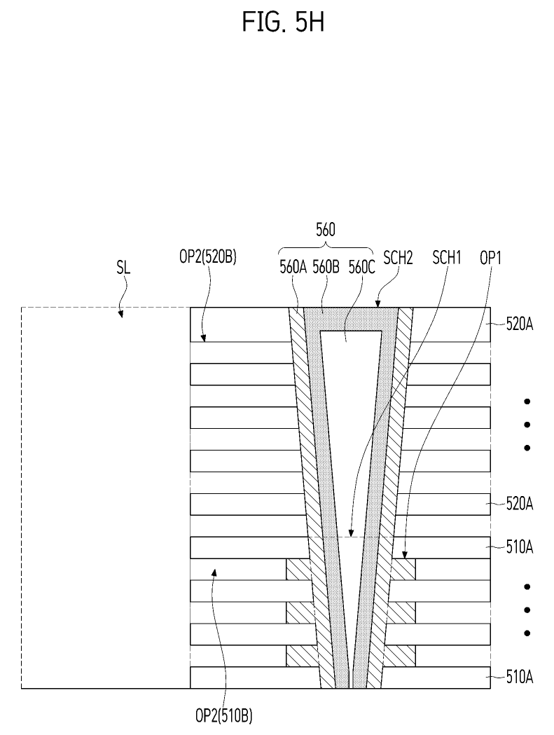

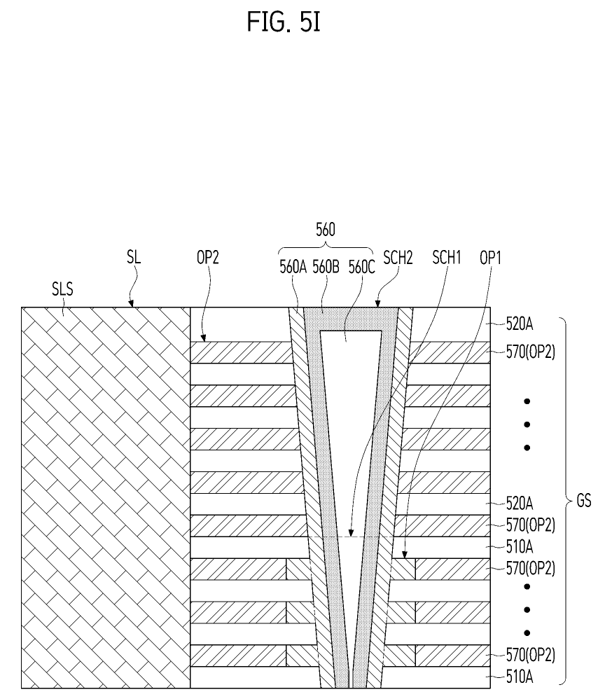

FIGS. 5A, 5B, 5C, 5D, 5E, 5F, 5G, 5H, and 5I are simplified diagrams illustrating a method of manufacturing a semiconductor device in accordance with an embodiment of the present disclosure. Hereinafter, content overlapping with previously described content may be omitted.

Referring to FIG. 5A, a first sub-stack 510S may be formed by alternately stacking first material layers 510A and second material layers 510B. Subsequently, a second sub-stack 520S may be formed by alternately stacking third material layers 520A and fourth material layers 520B. Here, the first material layers 510A and the third material layers 520A may each include an insulating material such as oxide, and the second material layers 510B and the fourth material layers 520B may each include a sacrificial material such as nitride.

Subsequently, a channel hole CHH extending through the first and second sub-stacks 510S and 520S may be formed. For example, a channel hole CHH including a first sub-channel hole SCH1 extending through the first sub-stack 510S and a second sub-channel hole SCH2 extending through the second sub-stack 520S and connected to the first sub-channel hole SCH1 may be formed.

The channel hole CHH may have a different width at different levels thereof. For example, the first sub-channel hole SCH1 may have a first width W1, and the second sub-channel hole SCH2 may have a second width W2 different from the first width W1. The channel hole CHH may have a width that decreases from the second sub-channel hole SCH2 toward the first sub-channel hole SCH1. For example, the first width W1 may be narrower than the second width W2. Here, the first and second widths W1 and W2 may be widths of the uppermost portions, widths of the lowermost portions, or widths of middle portions between the uppermost portions and the lowermost portions of the first and second sub-channel holes SCH1 and SCH2, respectively. The first width W1 of the uppermost portion of the first sub-channel hole SCH1 and the second width W2 of the lowermost portion of the second sub-channel hole SCH2 may be substantially the same as each other.

Referring to FIG. 5B, a sacrificial layer 530 may be formed in the first and second sub-channel holes SCH1 and SCH2. For example, the sacrificial layer 530 may include a first sub-sacrificial layer 530A filling the first sub-channel hole SCH1 and a second sub-sacrificial layer 530B filling a portion of the second sub-channel hole SCH2. Here, the sacrificial layer 530 may include a sacrificial material such as polysilicon or carbon.

Referring to FIG. 5C, the sacrificial layer 530 may be partially removed. For example, the second sub-channel hole SCH2 may be reopened by removing the second sub-sacrificial layer 530B. In this case, the fourth material layers 520B of the second sub-stack 520S may be exposed. For reference, a portion of the first sub-sacrificial layer 530A may be removed in this process. However, the second material layers 510B of the first sub-stack 510S might not be exposed.

Referring to FIG. 5D, an oxide layer 540 may be formed on the first sub-sacrificial layer 530A. For example, the oxide layer 540 may be formed on an upper surface of the first sub-sacrificial layer 530A. The oxide layer 540 may be formed by oxidizing the first sub-sacrificial layer 530A. Alternatively, the oxide layer 540 may be formed by depositing oxide or the like on the first sub-sacrificial layer 530A.

Protective patterns 550 may be formed through the second sub-channel holes SCH2. For example, the protective patterns 550 may be selectively formed on the fourth material layers 520B, respectively. The protective patterns 550 may be selectively deposited on the fourth material layers 520B. The oxide layer 540 may prevent the protective patterns 550 from being formed on the first sub-sacrificial layer 530A. The protective patterns 550 may prevent or reduce the etching of the fourth material layers 520B in a subsequent process. The protective patterns 550 may each include a different material from the oxide layer 540 and the first sub-sacrificial layer 530A. For example, the protective patterns 550 may each include at least one of silicon oxide carbide, silicon carbonitride, or titanium nitride.

Referring to FIG. 5E, the first sub-sacrificial layer 530A may be removed. For example, the first sub-channel hole SCH1 may be reopened. After the oxide layer 540 is removed, the first sub-sacrificial layer 530A may be removed. Alternatively, the oxide layer 540 and the first sub-sacrificial layer 530A may be removed simultaneously. In this case, the second material layers 510B of the first sub-stack 510S may be exposed. Because the protective patterns 550 each include the different material from the oxide layer 540 and the first sub-sacrificial layer 530A, the protective patterns 550 might not be removed in a process of removing the oxide layer 540 and the first sub-sacrificial layer 530A.

For example, the oxide layer 540 may not be formed on the first sub-sacrificial layer 530A. In such a case, the protective patterns 550 may remain without being removed in a process of removing the first sub-sacrificial layer 530A. This is because the protective patterns 550 include different material from the first sub-sacrificial layer 530A, and thus, only the first sub-sacrificial layer 530A may be selectively removed.

Referring to FIG. 5F, first openings OP1 expanding the first sub-channel hole SCH1 may be formed by partially etching the second material layers 510B. Consequently, the first sub-channel hole SCH1 may have a third width W3 greater than the first width W1 at levels corresponding to the second material layers 510B. A width of the first sub-channel hole SCH1 having the first width W1 that is relatively narrow compared to the second sub-channel hole SCH2 having the second width W2 that is relatively wide may be expanded to the third width W3. Subsequently, the protective patterns 550 may be removed.

Referring to FIG. 5G, a channel structure 560 may be formed on the sidewall of the second sub-channel hole SCH2, the first sub-channel hole SCH1, and may also fill the first openings OP1. For example, the memory layer 560A may be formed along the second sub-channel hole SCH2, the first sub-channel hole SCH1, and may fill the first openings OP1. Subsequently, a channel layer 560B may be formed on the memory layer 560A. Subsequently, an insulating core 560C may be formed on the channel layer 560B to fill the remainder of the first and second sub-channel holes SCH1 and SCH2.

In another embodiment, although not illustrated in FIG. 5G, at least one of the channel layer 560B or the insulating core 560C may be formed in the first openings OP1. The memory layer 560A, the channel layer 560B, and the insulating core 560C may be conformally formed in the second sub-channel hole SCH2, the first sub-channel hole SCH1, and the first openings OP1. In such a case, by forming the memory layer 560A, the channel layer 560B, and the insulating core 560C at a constant thickness, the channel layer 560B and the insulating core 560C may be formed in the first openings OP1.

When the first sub-channel hole is not expanded, the channel structure might not be completely formed in the channel hole having a width that decreases from an upper portion toward a lower portion. For example, a width of a lower region of the channel hole is relatively narrow, and thus, a space in which the channel layer is to be formed after the memory layer is formed may be insufficient. Alternatively, even though the memory layer and the channel layer are formed, a space in which the insulating core is to be formed may be insufficient.

According to an embodiment of the present disclosure, by forming the first openings OP1, it is possible to expand the first sub-channel hole SCH1. That is, the first openings OP1 may be formed to expand the lower portion of the first sub-channel hole SCH1, ensuring sufficient space for forming the channel layer and insulating core, thereby preventing deformation or incomplete formation of the channel structure. Hence, even though the memory layer 560A is formed in the first openings OP1, a space margin may still exist in the first sub-channel hole SCH1, such that the channel layer 560B and/or the insulating core 560C may be sufficiently formed. Thus, even though the channel hole CHH is initially formed in a shape in which the width decreases from the upper portion toward the lower portion, by forming the first openings OP1 to expand the first sub-channel hole SCH1 formed at a relatively lower portion, it is possible to prevent or reduce the formation of the channel structure 560 having an incomplete shape.

Referring to FIG. 5H, a slit SL extending through the second sub-stack 520S and the first sub-stack 510S may be formed. Subsequently, second openings OP2 may be formed by removing the second and fourth material layers 510B and 520B through the slit SL.

For reference, the channel structure may be a dummy channel structure and may be used as a support structure. When the support has a shape in which a width decreases from an upper portion toward a lower portion, support force of the support may be weak. According to an embodiment of the present disclosure, the support may have a shape in which a lower region thereof is expanded. In such a case, in a process of forming the second openings OP2 by removing the second and fourth material layers 510B and 420B through the slit SL, it is possible to prevent or reduce the bending of the first and second sub-stacks 510S and 520S through the support. For improving the structural stability during the formation of the second openings OP2, the channel structure that functions as a support is designed with an expanded lower region, which helps prevent bending of the first and second sub-stacks that might otherwise occur due to the overall tapered shape.

Referring to FIG. 5I, a gate structure GS may be formed by forming fifth material layers 570 in the second openings OP2, respectively. Here, the fifth material layers 570 may each include a conductive material such as tungsten. Subsequently, a slit structure SLS may be formed in the slit SL. Here, the slit structure SLS may include at least one of an insulating material, a conductive material, or a semiconductor material.

According to the method described above, the first openings OP1 expanding the first sub-channel hole SCH1 of the channel hole CHH formed at the relatively lower portion may be formed. In such a case, a space margin may be provided so that a structure to be formed in the channel hole CHH is formed in a complete shape. Alternatively, support force of the structure to be formed in the channel hole CHH may be improved.

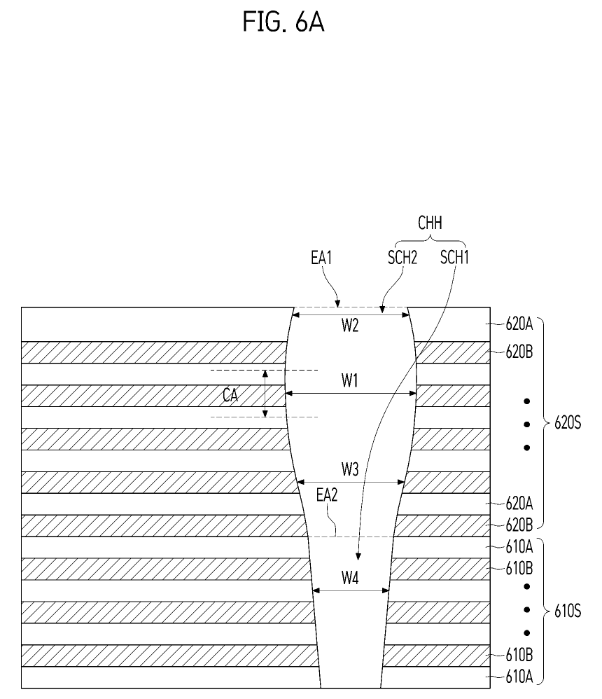

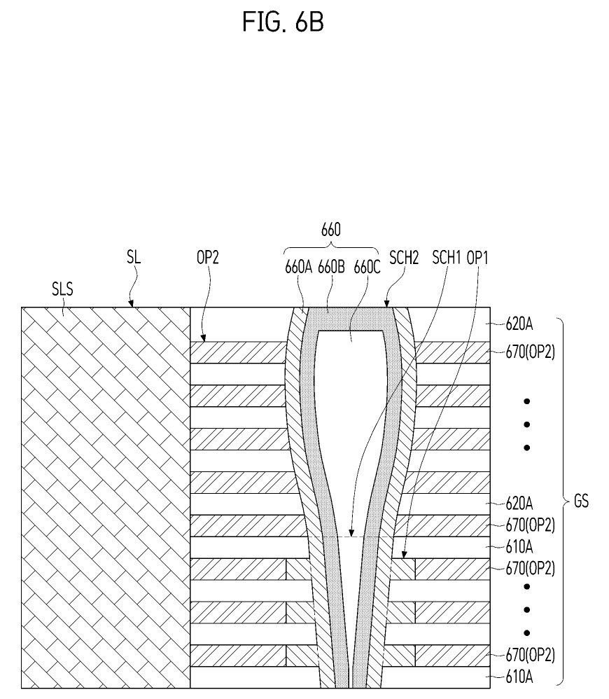

FIGS. 6A and 6B are simplified diagrams illustrating a method of manufacturing a semiconductor device in accordance with an embodiment of the present disclosure. Hereinafter, content overlapping with previously described content may be omitted.

Referring to FIG. 6A, a first sub-stack 610S may be formed by alternately stacking first material layers 610A and second material layers 610B. Subsequently, a second sub-stack 620S may be formed by alternately stacking third material layers 620A and fourth material layers 620B.

Subsequently, a channel hole CHH extending through the second sub-stack 620S and the first sub-stack 610S may be formed. The channel hole CHH may include a first sub-channel hole SCH1 extending through the first sub-stack 610S. The channel hole CHH may also include a second sub-channel hole SCH2 extending through the second sub-stack 620S and connected to the first sub-channel hole SCH1.

A shape of the channel hole CHH may be different from a shape of the channel hole CHH of FIG. 5A. For example, the channel hole CHH of FIG. 5A may have a tapered shape whose width constantly decreases from an upper portion toward a lower portion. On the contrary, the channel hole CHH of FIG. 6A may be formed in a bow shape whose sidewall has a curved surface at an upper portion, and may have a shape whose width decreases from a convex portion of the bow shape toward a lower portion. Such a difference may occur due to a difference in various manufacturing processes of semiconductor devices.

A sidewall of the second sub-channel hole SCH2 of FIG. 6A may have a curved surface. For example, the second sub-channel hole SCH2 may have a first width W1 that is a maximum width at a middle portion CA, and may have second and third widths W2 and W3 narrower than the first width W1 from the middle portion CA toward both ends EA1 and EA2. In addition, the first sub-channel hole SCH1 may have a fourth width W4 narrower than the third width W3 from the middle portion CA toward the first sub-channel hole SCH1 through the second end EA2.

Referring to FIGS. 5A to 5F and FIG. 6B, first openings OP1 may be formed for expanding the first sub-channel hole SCH1. Subsequently, a channel structure 660 may be formed in the second sub-channel hole SCH2, the first sub-channel hole SCH1, and the first openings OP1. Here, the channel structure 660 may include a memory layer 660A, a channel layer 660B, and an insulating core 660C.

Subsequently, a slit SL may be formed that extends through the second sub-stack 620S and the first sub-stack 610S. Subsequently, second openings OP2 may be formed by removing the second and fourth material layers 610B and 620B through the slit SL. Subsequently, fifth material layers 670 may be formed in the second openings OP2, respectively. Subsequently, a slit structure SLS may be formed by forming at least one of an insulating material, a conductive material, or a semiconductor material in the slit SL.

According to the method described above, the channel hole CHH may have the bow shape at the upper portion, and may have a shape in which the width decreases from the upper portion toward the lower portion, due to reasons of the manufacturing processes. In this case, the channel hole CHH formed at a relatively lower portion and having a relatively narrow width may be expanded. Accordingly, a space margin of a structure to be formed in the channel hole CHH may be secured, and support force of the structure to be formed in the channel hole CHH may be improved.

Although embodiments according to the technical concepts of the present disclosure have been described above with reference to the accompanying drawings, this is only for describing the embodiments according to the concept of the present disclosure, and the embodiments are not limited to the above embodiments. Various types of substitutions, modifications, and changes to the embodiments may be made by those skilled in the art, to which the present disclosure pertains, without departing from the technical idea of the present disclosure defined in the following claims, and it should be construed that these substitutions, modifications, and changes belong to the scope of the present disclosure. Furthermore, the embodiments may be combined to form additional embodiments.

What is claimed is:

1. A semiconductor device comprising:
a gate structure including a first sub-gate structure and a second sub-gate structure, the first sub-gate structure including first insulating layers and first conductive layers that are alternately stacked, and the second sub-gate structure being disposed on the first sub-gate structure and including second insulating layers and second conductive layers that are alternately stacked;
a first sub-channel structure extending through the first sub-gate structure and including a first portion and second portions protruding from the first portion toward the first sub-gate structure; and
a second sub-channel structure extending through the second sub-gate structure and connected to the first sub-channel structure.

2. The semiconductor device of claim 1, wherein the second portions protrude from the first portion toward the first conductive layers of the first sub-gate structure.

3. The semiconductor device of claim 1, wherein the second sub-channel structure has a width that decreases from an upper surface thereof to a lower surface thereof.

4. The semiconductor device of claim 1, wherein a sidewall of the second sub-channel structure has a curved surface.

5. The semiconductor device of claim 4, wherein the second sub-channel structure has a maximum width at a middle portion, and has a width that decreases from the middle portion toward both ends.

6. The semiconductor device of claim 1, wherein the first sub-channel structure comprises:
a first sub-memory layer included in the first portion and the second portions of the first sub-channel structure;
a first sub-channel layer disposed on the first sub-memory layer; and
a first sub-insulating core disposed on the first sub-channel layer.

7. The semiconductor device of claim 6, wherein the second sub-channel structure comprises:
a second sub-memory layer extending through the second sub-gate structure and connected to the first sub-memory layer;
a second sub-channel layer disposed on the second sub-memory layer and connected to the first sub-channel layer; and
a second sub-insulating core disposed on the first sub-channel layer and connected to the first sub-insulating core.

8. The semiconductor device of claim 1, further comprising:
a peripheral circuit disposed below the gate structure; and
a source structure disposed between the peripheral circuit and the gate structure.

9. The semiconductor device of claim 1, further comprising:
a peripheral circuit disposed below the gate structure;
a bonding structure disposed on the peripheral circuit; and
a source structure disposed on the gate structure.

10. The semiconductor device of claim 9, wherein the source structure is connected to the first sub-channel structure.

11. A semiconductor device comprising:
a stack including a first sub-stack and a second sub-stack, the first sub-stack including first material layers and second material layers that are alternately stacked, and the second sub-stack being disposed on the first sub-stack and including third material layers and fourth material layers that are alternately stacked;
a first through-structure extending through the first sub-stack and including a first portion and second portions protruding from the first portion toward the first sub-stack; and
a second through-structure extending through the second sub-stack and connected to the first through-structure.

12. The semiconductor device of claim 11, wherein the second portions protrude from the first portion toward the second material layers of the first sub-stack.

13. The semiconductor device of claim 11, wherein the second through-structure has a width that decreases from an upper surface thereof to a lower surface thereof.

14. The semiconductor device of claim 11, wherein a sidewall of the second through-structure has a curved surface.

15. The semiconductor device of claim 14, wherein the second through-structure has a maximum width at a middle portion, and has a width that decreases from the middle portion toward both ends.
